(19) United States
(12) Patent Application Publication
(10) Pub. No.: US 2024/0423055 A1
(43) Pub. Date: Dec. 19, 2024

(54) DISPLAY PANEL AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Ziyang YU, Beijing (CN); Zhiliang JIANG, Beijing (CN); Ming HU, Beijing (CN)

(21) Appl. No.: 18/701,591

(22) PCT Filed: Jun. 20, 2023
(86) PCT No.: PCT/CN2023/101391

§ 371 Date: Apr. 15, 2024

(30) Foreign Application Priority Data
Jun. 24, 2022 (CN) 202210729987.5

(51) Int. Cl. H10K 59/35; H10K 59/122; H10K 59/131

(52) U.S. Cl. CPC H10K 59/353; H10K 59/122; H10K 59/131; H10K 59/352

(57) ABSTRACT

A display panel is provided. The display panel includes a first display region. The first display region includes a plurality of sub-pixels. The plurality of sub-pixels are in one-to-one correspondence with a plurality of aperture regions, and light-emitting regions of the sub-pixel are randomly distributed within corresponding aperture regions.

### CROSS-REFERENCE TO RELATED APPLICATIONS

This application is a U.S. national phase application based on PCT/CN2023/101391, filed on Jun. 20, 2023, which claims priority to Chinese patent application No. 202210729987.5, filed on 24 Jun. 2022, entitled “DISPLAY PANEL AND DISPLAY DEVICE,” all of which are hereby incorporated by reference in their entireties for all purposes.

### TECHNICAL FIELD

The present disclosure relates to a display panel and a display device.

### BACKGROUND

With the development of display technologies, a display panel that supports an under-display camera function has become a research topic.

### SUMMARY

Embodiments of the present disclosure provide a display panel and a display device. The technical solutions of the present disclosure are described as follows.

In a first aspect of the embodiments of the present disclosure, a display panel is provided. The display panel includes a first display region. The first display region includes a plurality of sub-pixels, wherein the plurality of sub-pixels are in one-to-one correspondence with a plurality of aperture regions, and light-emitting regions of the sub-pixels are randomly distributed within corresponding aperture regions.

In some embodiments, the light-emitting regions of the sub-pixels being randomly distributed within the corresponding aperture regions includes at least one of: the light-emitting regions of the sub-pixels being randomly distributed in terms of position within the corresponding aperture regions: or the light-emitting regions of the sub-pixels being randomly distributed in terms of shape.

In some embodiments, a shape of the light-emitting region includes a closed pattern surrounded by a straight segment and/or a curved segment.

In some embodiments, a shape of the light-emitting region includes any one of a circle, an ellipse, a teardrop, a rounded rectangle, a rounded triangle, and a rounded trapezoid.

In some embodiments, shapes of the light-emitting regions of sub-pixels of a same light-emitting color in the plurality of sub-pixels are different.

In some embodiments, the display panel further includes a base substrate, wherein each of the sub-pixels includes a light-emitting structure, wherein the light-emitting region of the sub-pixel is an orthographic projection region of the light-emitting structure on the base substrate.

In some embodiments, each of the sub-pixels further includes an anode, wherein the anode is disposed on a side of the light-emitting structure close to the base substrate, and an orthographic projection of the anode on the base substrate covers the light-emitting region of the sub-pixel.

In some embodiments, a geometrical center of the light-emitting structure is coincident with a geometrical center of the anode.

In some embodiments, the anode includes an anode body and a connection portion connected to the anode body, wherein an orthographic projection of the anode body on the base substrate covers the light-emitting region of the sub-pixel, and the connection portion is configured to be connected a drive unit of the sub-pixel.

In some embodiments, the connection portion and the anode body are integrally formed.

In some embodiments, the connection portion extends randomly in a plane parallel to the base substrate.

In some embodiments, the plurality of sub-pixels are arranged in a plurality of first sub-pixel columns and a plurality of second sub-pixel columns, wherein the first sub-pixel columns and the second sub-pixel columns are arranged alternately along a first direction, each of the first sub-pixel columns includes first sub-pixels and second sub-pixels spaced apart along a second direction, and each of the second sub-pixel columns includes a plurality of third sub-pixels, the first direction being perpendicular to the second direction, and any two sub-pixels of the first sub-pixels, the second sub-pixels, and the third sub-pixels having different light-emitting colors:

the first sub-pixel columns and the second sub-pixel columns satisfy at least one of:

in a same first sub-pixel column, an included angle between a line connecting centers of the light-emitting regions of adjacent two of the first sub-pixels and the second sub-pixels and the second direction is an acute angle:

in any adjacent two of the first sub-pixel columns, an included angle between a line connecting a center of the light-emitting region of the first sub-pixel in one first sub-pixel column and a center of the light-emitting region of an adjacent second sub-pixel in the other first sub-pixel column and the first direction is an acute angle:

in a same second sub-pixel column, an included angle between a line connecting centers of the light-emitting regions of adjacent two of the third sub-pixels and the second direction is an acute angle:

in any adjacent two of the second sub-pixel columns, an included angle between a line connecting a center of the light-emitting region of the third sub-pixel in one second sub-pixel column and a center of the light-emitting region of an adjacent third sub-pixel in the other second sub-pixel column and the first direction is an acute angle: or

in any adjacent two of the first sub-pixel columns and the second sub-pixel columns, an included angle between a line connecting a center of the light-emitting region of the first sub-pixel and/or the second sub-pixel and a center of the light-emitting region of an adjacent third sub-pixel and the first direction is an acute angle.

In some embodiments, the display panel further includes a second display region, wherein the second display region includes the plurality of sub-pixels; and an area of the light-emitting region of any of the sub-pixels within the second display region is greater than an area of the light-emitting region of a sub-pixel within the first display region of a same light-emitting color as the any of the sub-pixels within the second display region.

In some embodiments, the second display region surrounds the first display region, and a boundary of the second display region is overlapped with a boundary of the first display region.

In some embodiments, the plurality of sub-pixels include red sub-pixels, green sub-pixels, and blue sub-pixels, wherein an area of a light-emitting region of the blue sub-pixel is greater than an area of a light-emitting region of the red sub-pixel, and the area of the light-emitting region of the blue sub-pixel is greater than an area of a light-emitting region of the green sub-pixel.

In some embodiments, a minimum distance between boundaries of adjacent two of the aperture regions is greater than or equal to a predetermined distance.

In some embodiments, the first display region is a display region in the display panel corresponding to an under-display camera device.

In some embodiments, the display panel is an organic light-emitting display panel.

In a second aspect of the embodiments of the present disclosure, a display device is provided. The display device includes the display panel according to the first aspect or any of the embodiments of the first aspect described above.

In some embodiments, the display device further includes the under-display camera device, wherein the under-display camera device is disposed on a non-display side of the display panel, and an orthographic projection of the under-display camera device on the display panel is within the first display region.

### BRIEF DESCRIPTION OF DRAWINGS

FIG. 1 is a front view of a display panel according to some embodiments of the present disclosure;

FIG. 2 is a diagram of a pixel arrangement within a first display region of the display panel illustrated in FIG. 1:

FIG. 3 is a diagram of an arrangement of an aperture region and the light-emitting region within the first display region illustrated in FIG. 2:

FIG. 4 is a diagram of an arrangement of the aperture region and anodes within the first display region illustrated in FIG. 2:

FIG. 5 is a diagram of another arrangement of an aperture region and anodes within a first display region of the display panel illustrated in FIG. 1;

FIG. 6 is a diagram of another pixel arrangement within a first display region of the display panel illustrated in FIG. 1;

FIG. 7 is a diagram of an arrangement of an aperture region and a light-emitting region within the first display region illustrated in FIG. 6:

FIG. 8 is a diagram of an arrangement of an aperture region and anodes within the first display region illustrated in FIG. 6; and

FIG. 9 is a schematic diagram of a display device according to some embodiments of the present disclosure.

### DETAILED DESCRIPTION

Embodiments of the present disclosure are described below in conjunction with the accompanying drawings. The embodiments set forth below are exemplary descriptions for explaining the technical solutions of the present disclosure, and do not constitute a limitation on the technical solutions of the present disclosure.

It is understood by those skilled in the art that, unless otherwise stated, the singular forms used in the present disclosure, such as “a,” “an,” “said,” “the,” and the like may also include the plural form. The term “include” and derivatives thereof as used in the specification of the present disclosure refer to the presence of the described features, integers, steps and/or operations, but does not exclude the implementation of other features, information, data, steps, operations and/or combinations thereof, etc., as supported in the art. The term “and/or” as used in the present disclosure refers to at least one of the items defined by the term, e.g., “A and/or B” may be implemented as “A,” or as “B,” or “A and B.”

The related technology involved in the present disclosure is first described below.

With the development of display technology, a display panel that supports an under-display camera function has become a research topic. A display region of a display panel supporting the under-display camera function includes an under-display camera region corresponding to an under-display camera device. When it is necessary to use the under-display camera device for shooting, sub-pixels of the under-display camera region are controlled to stop emitting light, and external light is irradiated to the under-display camera device through the under-display camera region to facilitate the imaging of the under-display camera device to achieve the functions of shooting and recording video. When there is no need to use the under-display camera device for shooting, the sub-pixels of the under-display camera region are controlled to emit light to achieve image display.

However, in the current display panel supporting the under-display camera function, the sub-pixels in the under-display camera region are arranged in an array. The sub-pixels in the under-display camera region are periodically arranged, and the sub-pixels have poor light transmittance. The sub-pixels in the under-display camera region are prone to forming a diffraction grating, which leads to diffraction of light from outside when the light passes through the under-display camera region. The light irradiated to the under-display camera device has a diffraction pattern, which is likely to cause interference to the imaging of the under-display camera device. Consequently, the imaging quality of the under-display camera device is poor.

Causes to the diffraction when external light passes through the under-display camera region of the display panel are illustrated using an organic light-emitting diode (OLED) display panel as an example.

A display region of the OLED display panel includes the sub-pixels in an array, and the sub-pixels emit light under current driving. A drive circuit of the sub-pixels controls the drive current of the sub-pixels by applying a drive voltage to the sub-pixels to control the light-emitting brightness of the sub-pixels. For the OLED display panel supporting the under-display camera function, in order to ensure the transmittance of the under-display camera region, the drive circuit of the sub-pixels within the under-display camera region is usually arranged outside the under-display camera region. An anode of the sub-pixel within the under-display camera region is connected to the drive circuit of the sub-pixels via a transparent electrode to apply a drive voltage to the sub-pixel via the drive circuit. The sub-pixels in the under-display camera region are periodically arranged, and the anodes of the sub-pixels are opaque, such that the anodes of the sub-pixels in the under-display camera region are prone to forming a diffraction grating, which results in diffraction of external light through the under-display camera region. The light irradiated to the under-display camera device has diffraction patterns, which causes interference to imaging of the under-display camera device, thereby causing a poor imaging quality of the under-display camera device and affecting the user experience.

Some embodiments of the present disclosure provide a display panel and a display device, wherein a first display region of the display panel is the under-display camera region and the first display region include a plurality of sub-pixels in one-to-one correspondence with a plurality of aperture regions. Light-emitting regions of the plurality of sub-pixels are randomly distributed in corresponding aperture regions, such that the probability that the light-emitting regions of the sub-pixels within the first display region are periodically arranged is reduced. In this way, the probability that the sub-pixels in the first display region form a diffraction grating is reduced, the diffraction when external light passes through the first display region is mitigated, and the imaging quality of the under-display camera device is ensured.

The technical solutions of the embodiments of the present disclosure are described below in conjunction with the accompanying drawings. The following different embodiments may be referenced to or combined with each other, and the same terms, similar features and the like in the different embodiments are not be described repeatedly.

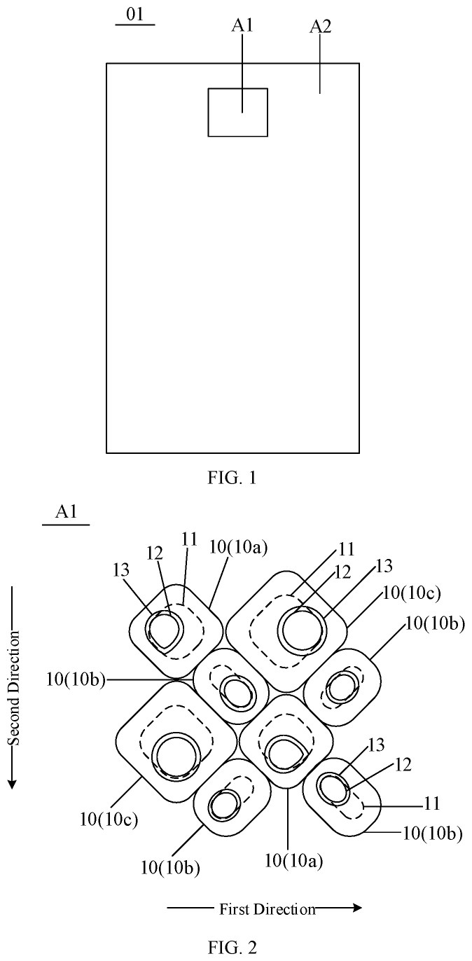

FIG. 1 illustrates a front view of a display panel 01 according to some embodiments of the present disclosure. The display panel 01 includes a first display region A1 and a second display region A2. The second display region A2 surrounds the first display region A1, and a boundary of the second display region A2 is overlapped with a boundary of the first display region A1. The first display region A1 is a display region in the display panel 01 corresponding to an under-display camera device (not illustrated in FIG. 1), and the first display region A1 may be referred to as an under-display camera region. The second display region A2 is a display region other than the first display region A1 within the display region of the display panel 01, and the second display region A2 is a normal display region. The first display region A1 and the second display region A2 both include a plurality of sub-pixels. The sub-pixels within the first display region A1 and the second display region A2 are both capable of emitting light for image display.

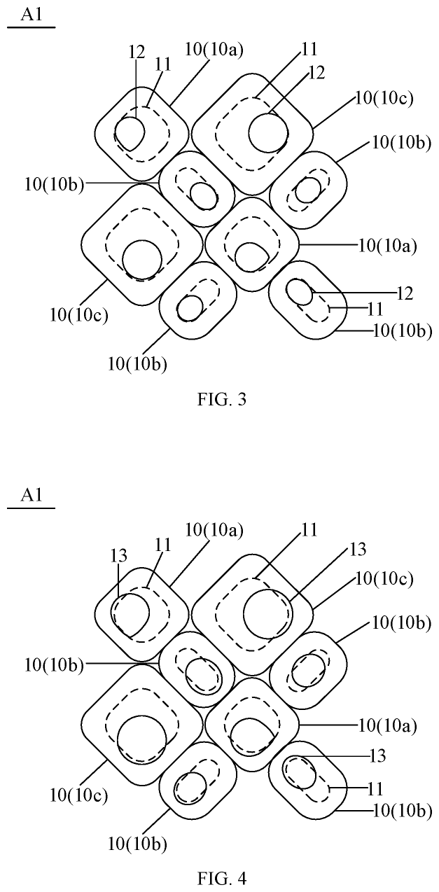

FIG. 2 is a diagram of a pixel arrangement within the first display region A1 of the display panel 01 illustrated in FIG. 1. As illustrated in FIG. 2, the first display region A1 includes a plurality of sub-pixels 10 in one-to-one correspondence with a plurality of aperture regions 11. Each sub-pixel 10 includes a light-emitting region 12, and the light-emitting region 12 of each sub-pixel 10 is a region of the sub-pixel 10 which is capable of emitting light. FIG. 3 is a diagram of an arrangement of the aperture region 11 and the light-emitting region 12 within the first display region A1 illustrated in FIG. 2. As illustrated in FIGS. 2 and 3, the light-emitting regions 12 of the sub-pixels 10 are randomly distributed within the aperture regions 11 corresponding to the sub-pixels 10.

In summary, in the display panel according to the embodiments of the present disclosure, the light-emitting regions of the sub-pixels in the first display region are randomly distributed within the aperture region corresponding to the sub-pixels, such that the probability that the light-emitting regions of the sub-pixels within the first display region are periodically arranged is reduced, and thus the probability that the sub-pixels within the first display region form a diffraction grating is reduced, which mitigates the diffraction when the external light passes through the first display region. Exemplarily, the first display region is the under-display camera region. Since the diffraction when external light passes through the first display region is mitigated. the imaging quality of the under-display camera device disposed on a non-display side of the display panel is ensured, and thus the user experience is ensured.

The display panel 01 includes a pixel definition layer (PDL). The aperture region 11 is defined by the PDL. The aperture region 11 is also referred to as a PDL permissive region. In some embodiments, the pixel definition layer is also referred to as a pixel boundary layer, and the aperture region 11 is also referred to as a pixel boundary region. In the embodiments of the present disclosure, a minimum distance between the boundaries of adjacent aperture regions is greater than or equal to a predetermined distance, such that color mixing of adjacent sub-pixels is avoided while guaranteeing the aperture ratio of the sub-pixels. Since the aperture region is defined by the PDL, the minimum distance between the boundaries of adjacent aperture regions is also referred to as a PDL gap, and a size of the PDL gap depends on the precision of a device for preparing the PDL and the precision of a vapor deposition process, or the like, which is not limited in the embodiments of the present disclosure.

In some embodiment, the random distribution of the light-emitting region 12 of any sub-pixel 10 within the first display region A1 within the corresponding aperture region 11 includes at least one of: the random distribution of a position of the light-emitting region 12 of the sub-pixel 10 within the corresponding aperture region 11: or the random distribution of a shape of the light-emitting region 12 of the sub-pixel 10. In some embodiments, the light-emitting region 12 is an opaque region, and the first display region A1 also includes a light-transmitting region, such that external light is irradiated to the under-display camera device through the first display region A1. In the embodiments of the present disclosure, the probability that the light-emitting regions 12 of the sub-pixels 10 are periodically arranged within the first display region A1 is reduced by defining the positions and/or shapes of the light-emitting regions 12 of the sub-pixels 10 within the first display region A1 to be randomly distributed, such that the probability that the light-emitting region 12 of the sub-pixel 10 within the first display region A1 forms a diffraction grating is reduced, and thus the diffraction when external light passes through the first display region A1 is mitigated. In this way, a diffraction pattern in an image captured by the under-display camera device is avoided, the imaging quality of the under-display camera device is ensured, and the user experience is ensured.

In some embodiments, FIGS. 2 and 3 are both front views, i.e., positions and/or shapes of the light-emitting regions 12 are randomly distributed in a plane parallel to a base substrate (not illustrated in any of FIGS. 1 to 3) of the display panel 01. The embodiments of the present disclosure indicate a range of the aperture region 11 with a dotted line in order to facilitate the expression of the positional relationship between the aperture region 11 and the light-emitting region 12. In fact, the dotted line does not exist in the actual display panel.

In the embodiments of the present disclosure, the shape of the light-emitting region 12 includes a closed pattern surrounded by a straight and/or a curved segment. The first display region A1 includes a variety of the light-emitting regions 12 with different shapes, such that the probability that the light-emitting regions 12 within the first display region A1 are periodically arranged is further reduced, and thus the probability that the light-emitting regions 12 of the sub-pixels 10 within the first display region A1 form a diffraction grating is further reduced. In this way, the imaging quality of the under-display camera device is ensured, and the user experience is ensured.

In some embodiments, the shape of the light-emitting region 12 may be a polygon such as a triangle, rectangle, square, trapezoid, etc. surrounded by straight segments, a circle, an ellipse, etc. surrounded by curved segments, or a pattern surrounded by straight segments and curved segments, which is not limited in the embodiments of the present disclosure. The shape of the light-emitting region 12 may be determined according to the actual production process and demand. In one example, the shape of the light-emitting region 12 includes any one of a circle, an ellipse, a teardrop, a rounded rectangle, a rounded triangle, and a rounded trapezoid.

In some embodiments of the present disclosure, the first display region A1 and the second display region A2 both include a plurality of sub-pixels (the sub-pixels within the second display region A2 are not illustrated in the drawings for the sake of simplicity), and the aperture regions corresponding to the sub-pixels within the second display region A2 are overlapped with the light-emitting regions of the sub-pixels, such that light-emitting areas of the sub-pixels within the second display region A2 are ensured, the aperture ratios of the sub-pixels within the second display region A2 are ensured, and the densities of the sub-pixels within the second display region A2 are increased. In some embodiments, the first display region A1 and the second display region A2 both include a plurality of sub-pixels with different light-emitting colors. An area of the light-emitting region of any of the sub-pixels within the second display region A2 is greater than an area of the light-emitting region 12 of a sub-pixel 10 of the same light-emitting color as that of the any of the sub-pixels within the first display region A1. Since the second display region A2 is a conventional display region, in the embodiments of the present disclosure, the area of the light-emitting region of any of the sub-pixels within the second display region A2 is set to be greater than the area of the light-emitting region 12 of the sub-pixel 10 of the same light-emitting color as that of the any of the sub-pixels within the first display region A1. In this way, the light transmittance rate of the first display region A1 is ensured, and the imaging quality of the under-display camera device is ensured. Furthermore, the aperture ratios of the sub-pixels within the second display region A2 is ensured, and the display effect of the display panel 01 is ensured.

In some embodiments, illustrated as an example of the sub-pixels of a tri-color, the first display region A1 and the second display region A2 both include red sub-pixels, green sub-pixels and blue sub-pixels. For example, as illustrated in FIGS. 2 and 3, the first display region A1 includes red sub-pixels 10a, green sub-pixels 10b, and blue sub-pixels 10c. The red sub-pixels have a luminescence color (i.e., the color of the light emitted) of red, the green sub-pixels have a luminescence color of green, and the blue sub-pixels have a luminescence color of blue. An area of a light-emitting region of the red sub-pixel within the second display region A2 is greater than an area of a light-emitting region 12 of the red sub-pixel 10a within the first display region A1, an area of the light-emitting region of the green sub-pixel within the second display region A2 is greater than an area of the light-emitting region 12 of the green sub-pixel 10b within the first display region A1 and an area of the light-emitting region of the blue sub-pixel within the second display region A2 is greater than an area of the light-emitting region 12 of the blue sub-pixel within the first display region A1. In other words, the area of the light-emitting region 12 of the red sub-pixel 10a within the first display region A1 is less than or equal to the area of the light-emitting region of the red sub-pixel within the second display region A2, the area of the light-emitting region 12 of the green sub-pixel 10b within the first display region A1 is less than or equal to the area of the light-emitting region of the green sub-pixel within the second display region A2, and the area of the light-emitting region 12 of the blue sub-pixel 10c within the first display region A1 is less than or equal to the area of the light-emitting region of the blue sub-pixel within the second display region A2.

In some embodiments, since the blue sub-pixels have a lower luminous efficiency, the area of the light-emitting region of the blue sub-pixel is set to be greater than the area of the light-emitting region of the red sub-pixel, and the area of the light-emitting region of the blue sub-pixel is set to be greater than the area of the light-emitting region of the green sub-pixel in the embodiments of the present disclosure. Exemplarily, as illustrated in FIGS. 2 and 3, within the first display region A1, the area of the light-emitting region 12 of the blue sub-pixel 10c is greater than the area of the light-emitting region 12 of the red sub-pixel 10a, and the area of the light-emitting region 12 of the blue sub-pixel 10c is greater than the area of the light-emitting region 12 of the green sub-pixel 10b.

In some embodiments of the present disclosure, the display panel 01 includes a base substrate, and the sub-pixel 10 includes a light-emitting structure. The light-emitting region 12 of any of the sub-pixels 10 is an orthographic projection region of the light-emitting structure of the any of the sub-pixels 10 on the base substrate. In some embodiments, the display panel 01 is an organic light-emitting display panel, the light-emitting structure is made of an organic light-emitting material, and the light-emitting structure is obtained by depositing the organic light-emitting material within the aperture region 11. Exemplarily, the display panel 01 is an OLED display panel.

In some embodiments, as illustrated in FIG. 2, the sub-pixel 10 further includes an anode 13. The anode 13 is on a side of the light-emitting structure close to the base substrate, i.e., the anode 13 is between the light-emitting structure and the base substrate. An orthographic projection of the anode 13 on the base substrate covers a corresponding light-emitting region. That is, the orthographic projection of the anode 13 on the base substrate covers an orthographic projection of the corresponding light-emitting structure on the base substrate. Exemplarily, the orthographic projection of the light-emitting structure on the base substrate is within the orthographic projection of the anode 13 on the base substrate. An area of the orthographic projection of the anode 13 on the base substrate is greater than an area of the orthographic projection of the light-emitting structure on the base substrate. A shape of the orthographic projection of the anode 13 on the base substrate is the same as that of the orthographic projection of the light-emitting structure on the base substrate. An anode body 131 follows a shape of the light-emitting structure. In this way, the drive efficiency of the anode 13 to the light-emitting structure is ensured, and thus the luminous efficiency of the light-emitting structure is ensured. FIG. 4 is a diagram of an arrangement of the anode 13 and the light-emitting region 12 within the first display region A1 illustrated in FIG. 2. As illustrated in FIGS. 2 and 4, since the orthographic projection of the anode 13 on the base substrate covers the orthographic projection of the corresponding light-emitting structure on the base substrate, a portion of the anode 13 is outside an aperture region 11, and the portion of the anode 13 outside the aperture region 11 is buried in a PDL for defining the aperture region 11.

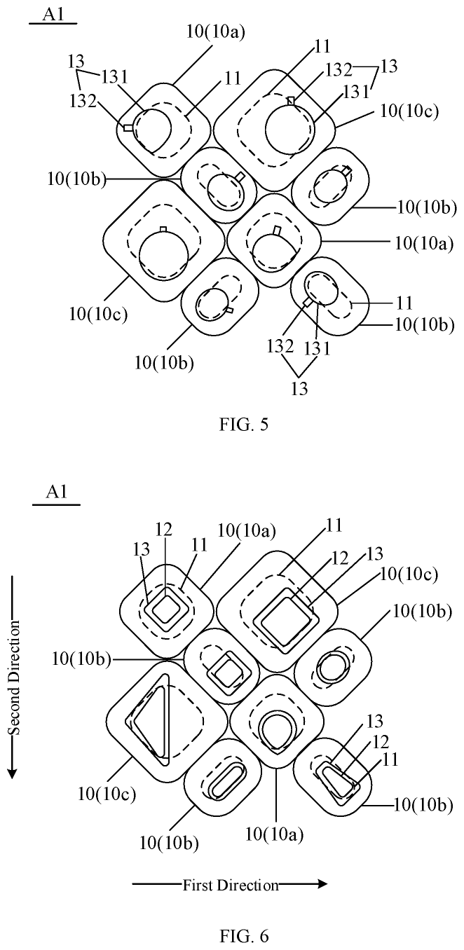

In some embodiments, FIG. 5 is a diagram of another arrangement of the anode 13 and the light-emitting region 12 within the first display region A1 of the display panel 01 illustrated in FIG. 1. As illustrated in FIG. 5, the anode 13 includes the anode body 131 and a connection portion 132 connected to the anode body 131. An orthographic projection of the anode body 131 on the base substrate covers the light-emitting region 12 of the sub-pixel 10 including the anode 13. The connection portion 132 is configured to be connected to a drive unit of the sub-pixel 10 including the anode 13, and is hence connected to a drive circuit of the sub-pixel 10, such that the drive circuit applies a drive voltage to the anode 13 via the drive unit to control the sub-pixel 10 to emit light. Exemplarily, the drive unit is a TFT.

In some embodiments, the connection portion 132 and the anode body 131 are integrally formed, and the connection portion 132 and the anode body 131 are prepared by a same patterning process. A demarcation line between the anode body 131 and the connection portion 132 is illustrated in FIG. 5 for ease of presentation of the anode body 131 and the connection portion 132. The demarcation line is not present in the display panel. In other embodiments, the connection portion 132 and the anode body 131 are prepared by two patterning processes, and the connection portion 132 is connected to the anode body 131, which is not limited in the embodiments of the present disclosure.

In some embodiments, the connection portions 132 extend randomly in a plane parallel to the base substrate. As illustrated in FIG. 5, the anode 13 of each of the sub-pixels 10 within the first display region A1 includes the connection portion 132, and extension directions of the connection portions 132 within the first display region A1 are randomly distributed in a plane parallel to the base substrate. Since the extension directions of the connection portions 132 within the first display region A1 are randomly distributed in a plane parallel to the base substrate, the probability that the connection portions 132 within the first display region A1 are periodically arranged is reduced. In this way, the probability that the connection portions 132 within the first display region A1 form a diffraction grating is reduced, the diffraction when the external light passes through the first display region A1 is mitigated, and the imaging quality of the under-display camera device is ensured, and thus the user experience is ensured.

Since the anode 13 is opaque, the anode 13 is set to include the anode body 131 and the connection portion 132 in the embodiments of the present disclosure, such that it is possible to connect the anode 13 to the drive unit via the connection portion 132, and it is possible to set the anode body 131 to be less to ensure the light transmittance of the first display region A1.

In some embodiments, as illustrated in FIGS. 2 and 3, the anode 13 does not include the connection portion 132. The anode 13 includes a portion for connecting to the drive unit, which is not limited in embodiments of the present disclosure.

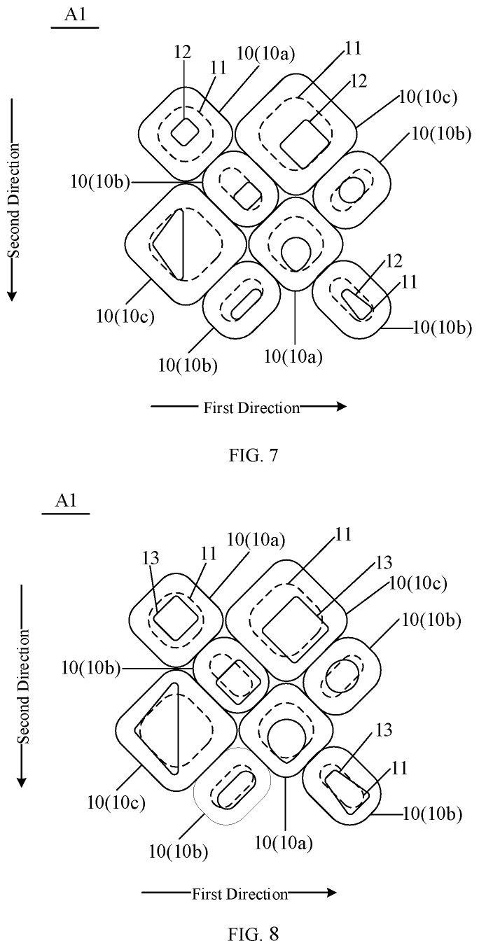

In some embodiments, a geometrical center of the light-emitting structure and a geometrical center of the anode 13 coincide in each of the sub-pixels 10 within the first display region A1. Exemplarily, FIG. 6 is a diagram of another pixel arrangement within the first display region A1 of the display panel 01 illustrated in FIG. 1. FIG. 7 is a diagram of an arrangement of the aperture region 11 and the light-emitting region 12 within the first display region A1 illustrated in FIG. 6. FIG. 8 is a diagram of an arrangement of the aperture region 11 and the anode 13 within the first display region A1 illustrated in FIG. 6. As illustrated in FIGS. 2 and 6, the geometrical center of the light-emitting structure of each of the sub-pixels 10 within the first display region A1 (i.e., the geometrical center of the light-emitting region 12) and the geometrical center of the anode 13 coincide. Since the geometrical center of the light-emitting structure and the geometrical center of the anode 13 coincide in each of the sub-pixels 10, the geometrical center of the light-emitting structure of each of the sub-pixels 10, the geometrical center of the anode 13 of each of the sub-pixels 10, and a light-emitting center of each of the sub-pixels 10 coincide, which facilitates determining, by means of a position of the geometrical center of the light-emitting structure and a position of the geometrical center of the anode 13, a position of the light-emitting center of the sub-pixel 10. In some embodiments of the present disclosure, the geometrical center of the regularly shaped light-emitting structure and the geometrical center of the regularly shaped anode 13 are both coincident with the light-emitting center of the sub-pixel 10. For the irregularly shaped light-emitting structure and the irregularly shaped anode 13, the light-emitting center of the sub-pixel 10 is determined according to the shapes of the light-emitting structure and the anode 13 actually prepared.

In some embodiments of the present disclosure, the shape of the light-emitting region 12 includes any one of a circle, an ellipse, a teardrop. a rounded rectangle, a rounded triangle, and a rounded trapezoid.

In one example, as illustrated in FIGS. 2 and 3, the shapes of the light-emitting regions 12 of the sub-pixels 10 within the first display region A1 include a circle, an ellipse, and a teardrop.

The circular light-emitting region 12, the elliptical light-emitting region 12, and the teardrop-shaped light-emitting region 12 are spaced apart. For example, the red sub-pixel 10a, the green sub-pixel 10b, and the blue sub-pixel 10c are spaced apart, and the light-emitting region 12 of the red sub-pixel 10a is in the shape of a teardrop, the light-emitting region 12 of the green sub-pixel 10b is in the shape of an ellipse, and the light-emitting region 12 of the blue sub-pixel 10c is in the shape of a circle. The circular light-emitting region 12, the ellipse light-emitting region 12, and the drop-shaped light-emitting region 12 are spaced apart in the embodiments of the present disclosure, such that the probability that the light-emitting regions 12 within the first display region A1 are periodically arranged is reduced, and thus the probability that the anodes 13 corresponding to the light-emitting regions 12 within the first display region A1 are periodically arranged is reduced. In this way, the probability that the anodes 13 within the first display region A1 form a diffraction grating is reduced, the diffraction when external light passes through the first display region A1 is mitigated, and the imaging quality of the under-display camera device disposed on the non-display side of the first display region A1 is ensured.

In another example, as illustrated in FIGS. 6 and 7, the shapes of the light-emitting regions 12 of the sub-pixels 10 within the first display region A1 include an ellipse, a teardrop, a rounded rectangle, a rounded triangle, and a rounded trapezoid. The shapes of the light-emitting regions 12 of at least portion of the sub-pixels 10 having the same light-emitting color are different. For example, the shapes of the light-emitting regions 12 of the red sub-pixels 10a include a teardrop and a rounded rectangle, the shapes of the green sub-pixels 10b include an ellipse, a rounded rectangle and a rounded trapezoid, and the shapes of the light-emitting regions 12 of the blue sub-pixels 10c include a rounded rectangle and a rounded triangle. In the embodiments of the present disclosure, the light-emitting regions 12 of the sub-pixels 10 within the first display region A1 include a plurality of different shapes, and the shapes of at least portion of the light-emitting regions 12 of the sub-pixels 10 having the same light-emitting color are different, such that the probability that the light-emitting regions 12 within the first display region A1 are periodically arranged is reduced, and thus the probability that the anodes 13 corresponding to the light-emitting regions 12 within the first display region A1 are periodically arranged is reduced. In this way, the probability that the anodes 13 within the first display region A1 form a diffraction grating is reduced, the diffraction when external light passes through the first display region A1 is mitigated, and the imaging quality of the under-display camera device disposed on the non-display side of the first display region A1 is ensured.

In the embodiments of the present disclosure, an include angle between a line connecting the centers of the light-emitting regions 12 of any two adjacent sub-pixels 10 within the first display region A1 and the first direction or the second direction is an acute angle, the first direction and the second direction are perpendicular, and both the first direction and the second direction are parallel to the base substrate of the display panel 01. As illustrated in FIGS. 2 and 6, include angles between lines connecting the centers of the light-emitting regions 12 of any two adjacent sub-pixels 10 and the first direction or the second direction are all acute angles, thereby causing the centers of the light-emitting regions 12 of any three adjacent sub-pixels 10 not to be in a same straight line. In this way, the probability that the light-emitting regions 12 of the sub-pixels 10 within the first display region A1 are periodically arranged is reduced, the probability that the sub-pixels 10 within the first display region A1 form a diffraction grating is reduced, the diffraction when external light passes through the first display region A1 is mitigated, and the imaging quality of the under-display camera device is ensured, and thus the user experience is ensured.

In some embodiments, the sub-pixels 10 within the first display region A1 are arranged in a plurality of first sub-pixel columns and a plurality of second sub-pixel columns, the first sub-pixel columns and the second sub-pixel columns are arranged alternately along a first direction. Each of the first sub-pixel columns includes a plurality of first sub-pixels and a plurality of second sub-pixels spaced apart along a second direction. Each of the second sub-pixel columns includes a plurality of third sub-pixels. The first direction is perpendicular to the second direction. Any two of the first sub-pixel, the second sub-pixel, and the third sub-pixel have different light-emitting colors. Exemplarily, the first sub-pixel is the red sub-pixel, the second sub-pixel is the blue sub-pixel, and the third sub-pixel is the green sub-pixel. As illustrated in FIGS. 2 and 6, the first display region A1 includes the first sub-pixel column and the second sub-pixel column arranged alternately along the first direction, the first sub-pixel column includes the first sub-pixel (i.e., the red sub-pixel 10a) and the second sub-pixel (i.e., the blue sub-pixel 10c) spaced apart along the second direction, and the second sub-pixel column includes the plurality of third sub-pixels (i.e., green sub-pixels 10b). In the embodiments of the present disclosure, the first sub-pixel column and the second sub-pixel column satisfy at least one of the following five cases.

A first case: In the same first sub-pixel column, an include angle between a line connecting centers of the light-emitting regions 12 of the adjacent first sub-pixel (i.e., the red sub-pixel 10a) and the second sub-pixel (i.e., the blue sub-pixel 10c) and the second direction is an acute angle. In this way, lines connecting centers of the light-emitting regions 12 of the three adjacent sub-pixels in the same first sub-pixel column are not in the same straight line, such that the probability that the light-emitting regions 12 of the sub-pixels 10 within the first display region A1 are periodically arranged is reduced, and thus the probability that the sub-pixels 10 within the first display region A1 form a diffraction grating is reduced.

A second case: In any two adjacent first sub-pixel columns, an include angle between a line connecting the center of the light-emitting region of the first sub-pixel in one first sub-pixel column (i.e., the red sub-pixel 10a) and the center of the light-emitting region 12 of the adjacent second sub-pixels in the other first sub-pixel column (i.e., the blue sub-pixel 10c) and the first direction is an acute angle. The adjacent second sub-pixel is a second sub-pixel in the other first sub-pixel column adjacent to the first sub-pixel in the one first sub-pixel column. In this way, the probability that the light-emitting regions 12 of the sub-pixels 10 within the first display region A1 are periodically arranged is reduced, and thus the probability that the sub-pixels 10 within the first display region A1 form a diffraction grating is reduced.

A third case: In the same second sub-pixel column, an include angle between a line connecting the centers of the light-emitting regions 12 of the adjacent third sub-pixels (i.e., the green sub-pixel 10b) and the second direction is an acute angle. In this way, lines connecting the centers of the light-emitting regions 12 of the three adjacent third sub-pixels in the same second sub-pixel column are not in the same straight line, such that the probability that the light-emitting regions 12 of the sub-pixels 10 within the first display region A1 are periodically arranged is reduced, and thus the probability that the sub-pixels 10 within the first display region A1 form a diffraction grating is reduced.

A fourth case: In any two adjacent second sub-pixel columns, an include angle between a line connecting the center of the light-emitting region of the third sub-pixel (i.e., the green sub-pixel 10b) in one second sub-pixel column and the center of the light-emitting region 12 of an adjacent third sub-pixel in the other second sub-pixel column and the first direction is an acute angle. The adjacent third sub-pixel is a third sub-pixel in the other second sub-pixel column adjacent to the third sub-pixel in the one second sub-pixel column. In this way, the probability that the light-emitting regions 12 of the sub-pixels 10 within the first display region A1 are periodically arranged is reduced, and thus the probability that the sub-pixels 10 within the first display region A1 form a diffraction grating is reduced.

A fifth case: In any adjacent first sub-pixel column and second sub-pixel column, an include angle between a line connecting the center of the light-emitting region 12 of the first sub-pixel (i.e. red sub-pixel 10a) and/or the second sub-pixel (i.e. blue sub-pixel 10c) and the center of the light-emitting region 12 of an adjacent third sub-pixel (i.e. green sub-pixel 10b) and the first direction is an acute angle. The adjacent third sub-pixel is a third sub-pixel in the second sub-pixel column adjacent to the first sub-pixel and/or the second sub-pixel in the first sub-pixel column. In this way, the probability that the light-emitting regions 12 of the sub-pixels 10 within the first display region A1 are periodically arranged is reduced, and thus the probability that the sub-pixels 10 within the first display region A1 form a diffraction grating is reduced.

In some embodiments, the shapes of the light-emitting regions 12 of any two first sub-pixels are different, the shapes of the light-emitting regions 12 of any two second sub-pixels are different, and the shapes of the light-emitting regions 12 of any two third sub-pixels are different. In this way, the probability that the light-emitting regions 12 of the sub-pixels 10 within the first display region A1 are periodically arranged is reduced, the probability that the sub-pixels 10 within the first display region A1 form a diffraction grating is reduced, the diffraction when external light passes through the first display region is mitigated, and the imaging quality of the under-display camera device disposed on the non-display side of the first display region is ensured.

The above only exemplarily describes the display panel according to the embodiments of the present disclosure, and structures in the display panel not covered in the description of the above embodiments are referred to the related technology and are not repeated herein.

Based on the same inventive concept, the embodiments of the present disclosure provide a display device. The display device includes the display panel 01 according to the above embodiments. In some embodiments, the display device further includes the under-display camera device. The under-display camera device is on a non-display side of the display panel 01. The orthographic projection of the under-display camera device on the display panel 01 is within the first display region A1 of the display panel 01.

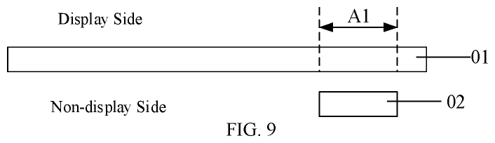

Exemplarily. FIG. 9 is a schematic diagram of a display device according to some embodiments of the present disclosure. As illustrated in FIG. 9, the display device includes a display panel 01 and an under-display camera device 02. The display panel 01 has a display side and a non-display side. The under-display camera device 02 is on the non-display side. An orthographic projection of the under-display camera device 02 on the display panel 01 is within a first display region A1 of the display panel 01. Since the light-emitting regions of the sub-pixels within the first display region A1 are randomly distributed, the probability that the light-emitting regions of the sub-pixels within the first display region A1 are periodically arranged is reduced. and the probability that the sub-pixels within the first display region A1 form a diffraction grating is reduced. In this way, the diffraction when external light is irradiated to the under-display camera device 02 through the first display region A1 is mitigated, a diffraction pattern in an image captured by the under-display camera device 02 is avoided, and the imaging quality of the under-display camera device 02 is ensured, and thus the user experience is ensured.

In some embodiments, the display device is a mobile phone, a tablet computer, a laptop computer, or a smart TV with an under-display camera function.

The above only exemplarily describes the display device of the present disclosure. The display device may also include other structures or components and other display devices, which are not limited in the embodiments of the present disclosure.

Based on the above description, it is seen that the technical solutions of the present disclosure achieve at least the following effects.

1. In the display panel 01 according to the embodiments of the present disclosure, the light-emitting regions 12 of the sub-pixels 10 within the first display region A1 are randomly distributed within the aperture regions 11 corresponding to the sub-pixels 10, such that the probability that the light-emitting regions 12 of the sub-pixels 10 within the first display region A1 are periodically arranged is reduced, and thus the probability that the sub-pixels 10 within the first display region A1 form a diffraction grating is reduced. In this way, the diffraction when light passes through the first display region A1 is mitigated, a diffraction pattern in an image captured by the under-display camera device disposed on the non-display side of the first display region A1 is avoided, and the imaging quality of the under-display camera device is ensured.

2. In the display panel 01 according to the embodiments of the present disclosure, the first display region A1 includes a plurality of light-emitting regions 12 with different shapes, such that the probability that the light-emitting regions 12 within the first display region A1 are periodically arranged is reduced, and thus the probability that the light-emitting regions 12 of the sub-pixels 10 within the first display region A1 form a diffraction grating is reduced. In this way, a diffraction pattern in an image captured by the under-display camera device disposed on the non-display side of the first display region A1 is avoided, and the imaging quality of the under-display camera device is ensured.

It is understood by those skilled in the art that the steps, measures, and solutions in the various operations, methods, and processes discussed in the present disclosure may be alternated, altered, combined, or deleted. Other steps, measures, and solutions in the various operations, methods, and processes discussed in the present disclosure may also be alternated, changed, rearranged, disassembled, combined, or deleted. In some practices, the steps, measures, and solutions in the various operations, methods, and processes discussed in the present disclosure may also be alternated, changed, rearranged, disassembled, combined, or deleted.

The terms “center,” “upper,” “lower,” “inner,” “outer,” and the like in the present disclosure indicate orientations or positions that are exemplary based on the illustrations illustrated in the accompanying drawings, and are intended to facilitate the description or simplification of the description of the embodiments of the present disclosure, and are not intended to indicate or imply that the device or component referred to must have a particular orientation, be constructed and operated with a particular orientation, and therefore are not to be understood as a limitation of the present disclosure.

The terms “first” and “second” are used for descriptive purposes only and are not to be understood as indicating or implying relative importance or implicitly specifying the number of technical features indicated. A feature defined with the terms “first” and “second” may expressly or implicitly include one or more the features. In the description of the present disclosure, unless otherwise indicated, “more than one” means two or more.

In the description of the present disclosure, unless otherwise expressly provided and limited, the term “connection” is to be understood in a broad sense, e.g., a fixed connection, a detachable connection, or a connection in one piece: or a direct connection, an indirect connection through an intermediate medium, or a connection within two elements. A person skilled in the art may understand the meaning of the above terms in the context of the present disclosure.

In the description of the specification, features, structures, materials, or characteristics may be combined in any one or more embodiments or examples in a suitable manner.

Described above are merely some exemplary embodiments of the present disclosure, and it should be noted that, for a person of ordinary skill in the art, without departing from the technical conception of the solution of the present disclosure, the use of other similar means of implementation based on the technical ideas of the present disclosure also falls within the scope of protection of the embodiments of the present disclosure.

1. A display panel, comprising a first display region; wherein
the first display region comprises a plurality of sub-pixels, wherein the plurality of sub-pixels are in one-to-one correspondence with a plurality of aperture regions, and light-emitting regions of the sub-pixels are randomly distributed within corresponding aperture regions.

2. The display panel according to claim 1, wherein the light-emitting regions of the sub-pixels being randomly distributed within the corresponding aperture regions comprises at least one of:
the light-emitting regions of the sub-pixels being randomly distributed in terms of position within the corresponding aperture regions; or
the light-emitting regions of the sub-pixels being randomly distributed in terms of shape.

3. The display panel according to claim 1, wherein a shape of the light-emitting region comprises a closed pattern surrounded by a straight segment and/or a curved segment.

4. The display panel according to claim 1, wherein a shape of the light-emitting region comprises any one of a circle, an ellipse, a teardrop, a rounded rectangle, a rounded triangle, and a rounded trapezoid.

5. The display panel according to claim 1, wherein shapes of the light-emitting regions of sub-pixels of a same light-emitting color in the plurality of sub-pixels are different.

6. The display panel according to claim 1, further comprising a base substrate; wherein each of the sub-pixels comprises a light-emitting structure, wherein the light-emitting region of the sub-pixel is an orthographic projection region of the light-emitting structure on the base substrate.

7. The display panel according to claim 6, wherein each of the sub-pixels further comprises an anode, wherein the anode is disposed on a side of the light-emitting structure close to the base substrate, and an orthographic projection of the anode on the base substrate covers the light-emitting region of the sub-pixel.

8. The display panel according to claim 7, wherein a geometrical center of the light-emitting structure is coincident with a geometrical center of the anode.

9. The display panel according to claim 7, wherein the anode comprises an anode body and a connection portion connected to the anode body, wherein an orthographic projection of the anode body on the base substrate covers the light-emitting region of the sub-pixel, and the connection portion is configured to be connected a drive unit of the sub-pixel.

10. The display panel according to claim 9, wherein the connection portion and the anode body are integrally formed.

11. The display panel according to claim 9, wherein the connection portion extends randomly in a plane parallel to the base substrate.

12. The display panel according to claim 1, wherein
the plurality of sub-pixels are arranged in a plurality of first sub-pixel columns and a plurality of second sub-pixel columns; wherein
the first sub-pixel columns and the second sub-pixel columns are arranged alternately along a first direction, each of the first sub-pixel columns comprises first sub-pixels and second sub-pixels spaced apart along a second direction, and each of the second sub-pixel columns comprises a plurality of third sub-pixels, the first direction being perpendicular to the second direction, and any two sub-pixels of the first sub-pixels, the second sub-pixels, and the third sub-pixels having different light-emitting colors;
the first sub-pixel columns and the second sub-pixel columns satisfy at least one of:
in a same first sub-pixel column, an included angle between a line connecting centers of the light-emitting regions of adjacent two of the first sub-pixels and the second sub-pixels and the second direction is an acute angle;
in any adjacent two of the first sub-pixel columns, an included angle between a line connecting a center of the light-emitting region of the first sub-pixel in one first sub-pixel column and a center of the light-emitting region of an adjacent second sub-pixel in the other first sub-pixel column and the first direction is an acute angle;
in a same second sub-pixel column, an included angle between a line connecting centers of the light-emitting regions of adjacent two of the third sub-pixels and the second direction is an acute angle;
in any adjacent two of the second sub-pixel columns, an included angle between a line connecting a center of the light-emitting region of the third sub-pixel in one second sub-pixel column and a center of the light-emitting region of an adjacent third sub-pixel in the other second sub-pixel column and the first direction is an acute angle; or
in any adjacent two of the first sub-pixel columns and the second sub-pixel columns, an included angle between a line connecting a center of the light-emitting region of the first sub-pixel and/or the second sub-pixel and a center of the light-emitting region of an adjacent third sub-pixel and the first direction is an acute angle.

13. The display panel according to claim 1, further comprising a second display region; wherein
the second display region comprises the plurality of sub-pixels; and
an area of the light-emitting region of any of the sub-pixels within the second display region is greater than an area of the light-emitting region of a sub-pixel within the first display region of a same light-emitting color as the any of the sub-pixels within the second display region.

14. The display panel according to claim 13, wherein the second display region surrounds the first display region, and a boundary of the second display region is overlapped with a boundary of the first display region.

15. The display panel according to claim 1 wherein the plurality of sub-pixels comprises red sub-pixels, green sub-pixels, and blue sub-pixels, wherein an area of a light-emitting region of the blue sub-pixel is greater than an area of a light-emitting region of the red sub-pixel, and the area of the light-emitting region of the blue sub-pixel is greater than an area of a light-emitting region of the green sub-pixel.

16. The display panel according to claim 1, wherein a minimum distance between boundaries of adjacent two of the aperture regions is greater than or equal to a predetermined distance.

17. The display panel according to claim 1, wherein the first display region is a display region in the display panel for corresponding to an under-display camera device.

18. The display panel according to claim 1, wherein the display panel is an organic light-emitting display panel.

19. A display device, comprising a display panel, wherein the display panel comprises a first display region; wherein
the first display region comprises a plurality of sub-pixels, wherein the plurality of sub-pixels are in one-to-one correspondence with a plurality of aperture regions, and light-emitting regions of the sub-pixels are randomly distributed within corresponding aperture regions.

20. The display device according to claim 19, further comprising the under-display camera device; wherein the under-display camera device is disposed on a non-display side of the display panel, and an orthographic projection of the under-display camera device on the display panel is disposed within the first display region.
